(19) United States
(12) Patent Application Publication
(10) Pub. No.: US 2026/0371693 A1
(43) Pub. Date: Nov. 19, 2026

(54) METHOD OF FORMING NANOSTRUCTURE DEVICE AND RELATED STRUCTURE

(71) Applicant: Taiwan Semiconductor Manufacturing Co., Ltd., Hsinchu (TW)

(72) Inventors: Tefu YEH, Hsinchu (TW); Chun-Chih CHENG, Hsinchu (TW); Cheng-Chieh TU, Hsinchu (TW); Jo-Chun HUNG, Hsinchu (TW); Ying-Liang CHUANG, Hsinchu (TW)

(73) Assignee: Taiwan Semiconductor Manufacturing Co., Ltd., Hsinchu (TW)

(21) Appl. No.: 19/755,268

(22) Filed: Jul. 27, 2026

Related U.S. Application Data
(62) Division of application No. 18/596,416, filed on Mar. 5, 2024.

(51) Int. Cl. H10D 64/27; H10D 30/01; H10D 30/43; H10D 30/67; H10D 62/10; H10D 64/01; H10D 64/23; H10D 64/66; H10D 84/83; H10P 50/28

(52) U.S. Cl. CPC H10D 64/514; H10D 30/014; H10D 30/43; H10D 30/6735; H10D 30/6757; H10D 62/121; H10D 64/017; H10D 64/667; H10D 84/83; H10P 50/283; H10D 64/258

(57) ABSTRACT

A method includes: forming a stack of alternating first semiconductor channels and second semiconductor layers on a substrate; releasing the first semiconductor channels by removing the second semiconductor layers; forming a gate dielectric on the first semiconductor channels; forming a transition metal nitride layer on the gate dielectric; and exposing the gate dielectric in a first region of the substrate by removing the transition metal nitride layer. The removing includes: performing a first etch using an acidic etchant; and after the performing a first etch, performing a second etch using an oxidizing etchant.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrammatic cross-sectional side views of a portion of an IC device according to embodiments of the present disclosure.

FIGS. 2A-13 are views of various embodiments of an IC device of at various stages of fabrication according to various aspects of the present disclosure.

FIG. 14 is a flowchart of a method of forming an IC device in accordance with various embodiments.

FIG. 15 is a flowchart of a method of forming an IC device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

The present disclosure is generally related to semiconductor devices, and more particularly to field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like.

Dielectric layers, such as HfO2, SiO2 and ZrO2 offer benefits for turning on field effect transistors. Quality of the dielectric layers can include thickness, vacancies, heterogeneous atom contamination and the like, which can beneficial or detrimental effects on threshold voltage (Vt), channel resistance (Rch), ring performance (RO %), time-dependent-dielectric-breakdown (TDDB), maximum voltage degradation and the like of the FETs. Some of the detrimental effects can arise after ten years or more of operation of the FETs. In the case of nanostructure devices, such as nanosheet FETs, dielectrics at sheet corners undergo dry bombardment, which can result in a stress concentration effect and degradation of film quality. Then, a subsequent wet chemical etching or cleaning that is performed to remove metal can damage the underlying dielectric film. For example, N-type metal patterning can result in BARC (bottom anti-reflective coating) etching by plasma bombardment on dielectric layer, which can reduce film quality. In another example, metal etching by wet chemical(s) may have low selectivity to the dielectric layer due to reduced film quality.

Embodiments of the disclosure effectively reduce or eliminate damage to the dielectric layer by including a high-selectivity wet etching process that simultaneously etches metal without removing the dielectric layer. Nanosheet corners, which can be a hot spot for damage, represent a challenge for reliability testing. In the wet etching process, higher H₂O₂ concentration can slightly increase metal to dielectric film selectivity. In another example, slight acidic addition (e.g., HCl) can improve dielectric film quality by reducing damage thereto. The embodiments can provide benefits, such as SRAM (static random access memory) yield improvements due to reduced leakage current, improvements in dielectric quality, mobility increases and ring oscillator performance (e.g., RO %) increases, device lifetime increases, reduced voltage degradation and the like.

The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure structure.

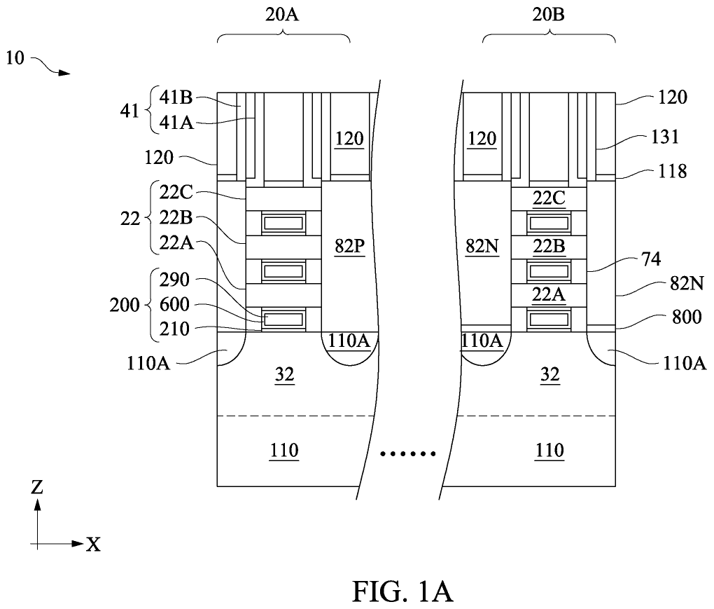

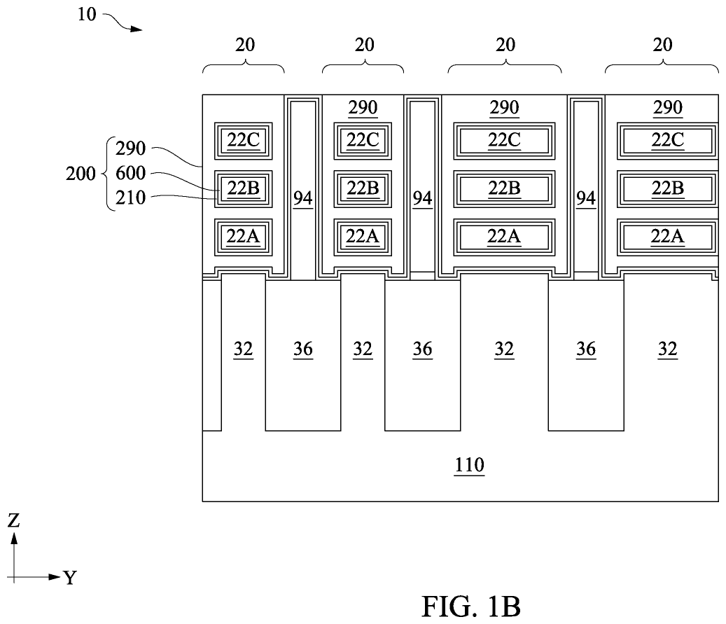

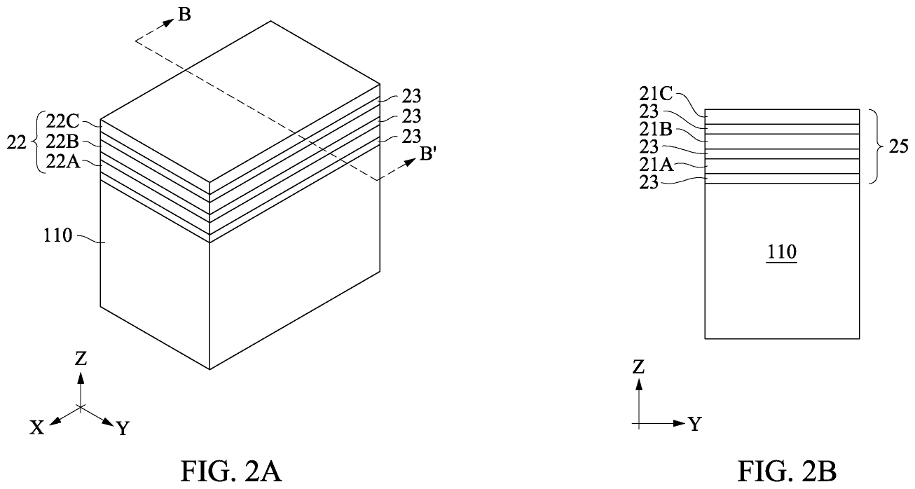

FIGS. 1A and 1B are diagrammatic cross-sectional side views of a portion of a nanostructure device 10 in accordance with various embodiments. FIG. 1A illustrates a view in an X-Z plane. FIG. 1B illustrates a view in a Y-Z plane orthogonal to the X-Z plane. The nanostructure device 10 of FIGS. 1A, 1B is described in detail below to provide context for understanding the technical features and benefits of the various embodiments depicted in FIGS. 2A-13. Source/drain region(s) may refer to a source or a drain, individually or collectively dependent upon the context.

Referring to FIG. 1A, nanostructure devices 20A, 20B may be or include one or more N-type FETs (NFETs) or P-type FETs (PFETs). For example, the nanostructure device 20A may be a PFET and the nanostructure device 20B may be an NFET. The nanostructure devices 20A, 20B are formed over and/or in a substrate 110, and generally include gate structures 200 straddling and/or wrapping around semiconductor channels 22A, 22B, 22C, alternately referred to as “nanostructures,” located over semiconductor fins 32 protruding from, and separated by, isolation structures 36 (see FIG. 1B). The semiconductor channels 22A, 22B, 22C may be referred to collectively as channels 22. The gate structure 200 controls electrical current flow through the channels 22A, 22B, 22C.

The nanostructure devices 20A, 20B are shown including three channels 22A, 22B, 22C, which are laterally abutted by source/drain features 82N, 82P, and covered and surrounded by the gate structure 200. Generally, the number of channels 22 is two or more, such as three or four or more. The gate structure 200 controls flow of electrical current through the channels 22A, 22B, 22C to and from the source/drain features 82N, 82P based on voltages applied at the gate structure 200 and at the source/drain features 82N, 82P.

In some embodiments, the fin structure 32 includes silicon. In some embodiments, the nanostructure device 20B includes an NFET, and the source/drain features 82N thereof include silicon phosphorous (SiP), SiAs, SiSb, SiPAs, SiP: As: Sb, combinations thereof, or the like. In some embodiments, the nanostructure device 20A includes a PFET, and the source/drain features 82P thereof include silicon germanium (SiGe), either undoped or doped to form, for example, SiGe: B, SiGe: B: Ga, SiGe: Sn, SiGe: B: Sn, or another appropriate semiconductor material. Generally, the source/drain features 82N, 82P may include any combination of appropriate semiconductor material(s) and appropriate dopant(s).

The channels 22A, 22B, 22C each include a semiconductive material, for example silicon or a silicon compound, such as silicon germanium, or the like. The channels 22A, 22B, 22C are nanostructures (e.g., having sizes that are in a range of a few nanometers) and may also each have an elongated shape and extend in the X-direction. In some embodiments, the channels 22A, 22B, 22C each have a nanowire (NW) shape, a nanosheet (NS) shape, a nanotube (NT) shape, or other suitable nanoscale shape. The cross-sectional profile of the channels 22A, 22B, 22C may be rectangular, round, square, circular, elliptical, hexagonal, or combinations thereof.

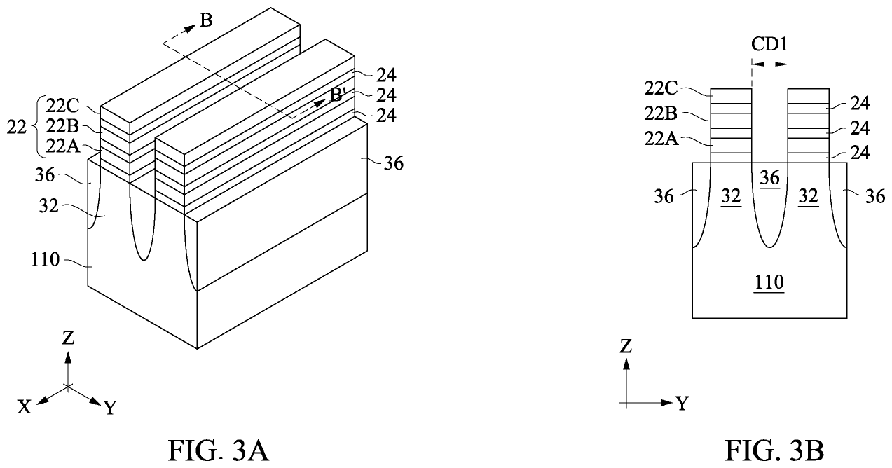

In some embodiments, the lengths (e.g., measured in the X-direction) of the channels 22A, 22B, 22C may be different from each other, for example due to tapering during a fin etching process (see FIGS. 3A, 3B). In some embodiments, length of the channel 22C may be less than a length of the channel 22B, which may be less than a length of channel 22A. The channels 22A, 22B, 22C each may not have uniform thickness (e.g., along the X-axis direction), for example due to a channel trimming process used to expand spacing (e.g., measured in the Z-axis direction) between the channels 22A, 22B, 22C to increase gate structure fabrication process window. For example, a middle portion of each of the channels 22A, 22B, 22C may be thinner than the two ends of each of the channels 22A, 22B, 22C. Such shape may be collectively referred to as a “dog-bone” shape.

In some embodiments, the spacing between the channels 22A, 22B, 22C (e.g., between the channel 22B and the channel 22A or the channel 22C) is in a range between about 8 nanometers (nm) and about 12 nm, though ranges exceeding or below the said range may also be beneficial. In some embodiments, a thickness (e.g., measured in the Z-direction) of each of the channels 22A, 22B, 22C is in a range between about 5 nm and about 8 nm, though ranges exceeding or below the said range may also be beneficial. In some embodiments, a width (e.g., measured in the Y-direction, orthogonal to the X-Z plane) of each of the channels 22A, 22B, 22C is at least about 8 nm, however the width may be less than 8 nm in some embodiments.

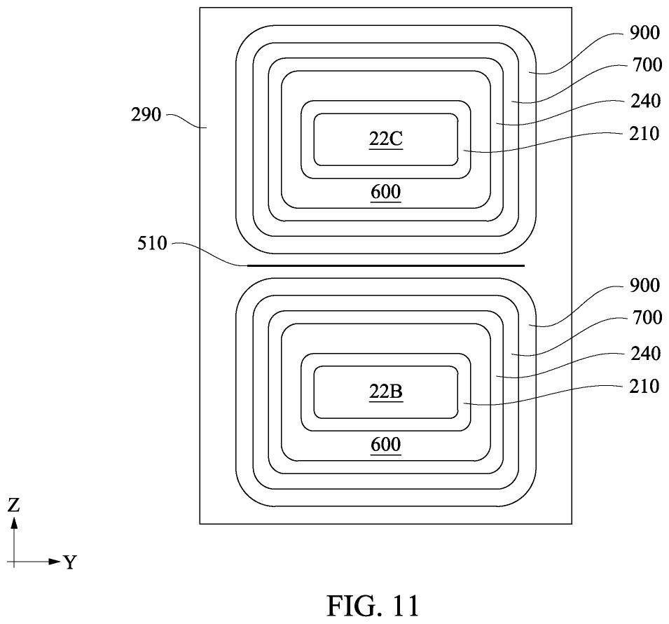

The gate structure 200 is disposed over and between the channels 22A, 22B, 22C, respectively. In some embodiments, the gate structure 200 is disposed over and between the channels 22A, 22B, 22C, which are silicon channels for N-type devices or silicon germanium channels for P-type devices. In some embodiments, the gate structure 200 includes an interfacial layer (IL) 210, one or more gate dielectric layers 600 on the interfacial layer 210 and a metal core layer 290 on the gate dielectric layer 600. Additional layers, such as one or more work function tuning layers 900 (see FIG. 11) may be present on the gate dielectric layer 600 between the gate dielectric layer 600 and the metal core layer 290.

The interfacial layer 210, which may be an oxide of the material of the channels 22A, 22B, 22C, is formed on exposed areas of the channels 22A, 22B, 22C and the top surface of the fin 32. The interfacial layer 210 promotes adhesion of the gate dielectric layers 600 to the channels 22A, 22B, 22C. In some embodiments, the interfacial layer 210 has thickness of about 5 Angstroms (A) to about 50 Angstroms (A). In some embodiments, the interfacial layer 210 has thickness of about 10 A. The interfacial layer 210 having thickness that is too thin may exhibit voids or insufficient adhesion properties. The interfacial layer 210 being too thick consumes gate fill window, which is related to threshold voltage tuning and resistance. In some embodiments, the interfacial layer 210 is doped with a dipole, such as lanthanum, for threshold voltage tuning.

In some embodiments, the gate dielectric layer 600 includes at least one high-k gate dielectric material, which may refer to dielectric materials having a high dielectric constant that is greater than a dielectric constant of silicon oxide (k≈3.9). Example high-k dielectric materials include HfO₂, HfSiO, HfSiON, HfTaO, HfTiO, HfZrO, ZrO₂, Ta₂O₅, or combinations thereof. In some embodiments, the gate dielectric layer 600 has thickness of about 5 A to about 100 A. The gate dielectric layer 600 may be a single layer or a multilayer.

The gate structure 200 also includes metal core layer 290. The metal core layer 290 may include a conductive material such as Co, W, Ru, combinations thereof, or the like. In some embodiments, the metal core layer 290 is or includes a Co-, W-or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. Between the channels 22A, 22B, 22C, the metal core layer 290 is circumferentially surrounded (in the cross-sectional view) by the one or more work function metal layers 900, which are then circumferentially surrounded by the gate dielectric layers 600, which are circumferentially surrounded by the interfacial layer 210.

As depicted in FIG. 1A, the nanostructure devices 20A, 20B may further include source/drain contacts 120 that are formed over the source/drain features 82N, 82P. The source/drain contacts 120 may include a core layer that is or includes a conductive material such as tungsten, ruthenium, cobalt, copper, titanium, titanium nitride, tantalum, tantalum nitride, iridium, molybdenum, nickel, aluminum, or combinations thereof. The core layer may be surrounded by one or more liner (or, “barrier”) layers, such as SiN or TiN, which help prevent or reduce diffusion of materials from and into the source/drain contacts 120. In some embodiments, height of the source/drain contacts 120 may be in a range of about 1 nm to about 50 nm.

Silicide layers 118 may be positioned between the source/drain features 82N, 82P and the source/drain contacts 120, at least to reduce the source/drain contact resistance. In some embodiments, the silicide layer 118 is or includes TiSi, CrSi, TaSi, MoSi, ZrSi, HfSi, ScSi, Ysi, HoSi, TbSI, GdSi, LuSi, DySi, ErSi, YbSi, or the like. In some embodiments, the silicide layer 118 is or includes NiSi, CoSi, MnSi, Wsi, FeSi, RhSi, PdSi, RuSi, PtSi, IrSi, OsSi, or the like. The silicide layer 118 may have thickness in a range of about 1 nm to about 10 nm. Thickness lower than about 1 nm may lead to an insufficient reduction in contact resistance. Thickness above about 10 nm may cause electrical shorting with the nanostructures 22. In some embodiments, the silicide layer 118 is present below, and in contact with, etch stop layer 131.

As depicted in FIG. 1B, the nanostructure devices 20A, 20B may further include an interlayer dielectric (ILD) 130. The ILD 130 provides electrical isolation between the various components of the nanostructure devices 20A, 20B discussed above, for example between neighboring pairs of the source/drain contacts 120. An etch stop layer 131 may be formed prior to forming the ILD 130 and may be positioned laterally between the ILD 130 and the gate spacers 41 and vertically between the ILD 130 and the source/drain features 82N, 82P. In some embodiments, the etch stop layer 131 is or includes SiN, SiCN, SiC, SiOC, SiOCN, HfO2, ZrO2, ZrAlOx, HfAlOx, HfSiOx, Al2O3, or other suitable material. In some embodiments, thickness of the etch stop layer 131 is in a range of about 1 nm to about 5 nm. In some embodiments, where the ILD 130 is not present (e.g., is removed completely prior to formation of the source/drain contacts 120), the etch stop layer 131 may be in contact with the source/drain contact 120. The etch stop layer 131 may be trimmed, for example, in the X-axis direction prior to formation of the source/drain contact 120 to improve fill quality of the source/drain contact 120.

The nanostructure devices 20A, 20B include gate spacers 41 that are disposed on sidewalls of the metal core layer 290, the gate dielectric layer 600 and the IL 210 above the channel 22A, and inner spacers 74 that are disposed on sidewalls of the IL 210 and/or the gate dielectric layer 600 between the channels 22A, 22B, 22C. The inner spacers 74 are also disposed between the channels 22A, 22B, 22C. In the embodiment depicted in FIG. 1A, the gate spacers 41 include a first spacer layer 41A and a second spacer layer 41B on the first spacer layer 41A. The first and second spacer layers 41A, 41B may each include a dielectric material, for example a low-k material such as SiOCN, SiON, SiN, SiCN, SiOC or the like. In some embodiments, the second spacer layer 41B is not present. Material of the first and second spacer layers 41A, 41B may be the same as or different from each other. In some embodiments, an upper portion of the second spacer layer 41B (or the first spacer layer 41A when the second spacer layer 41B is not present) may be removed partially or fully to increase aspect ratio of an opening through which the source/drain region 82N, 82P is formed. FIG. 1A depicts an embodiment in which the upper portion of the second spacer layer 41B is not thinned.

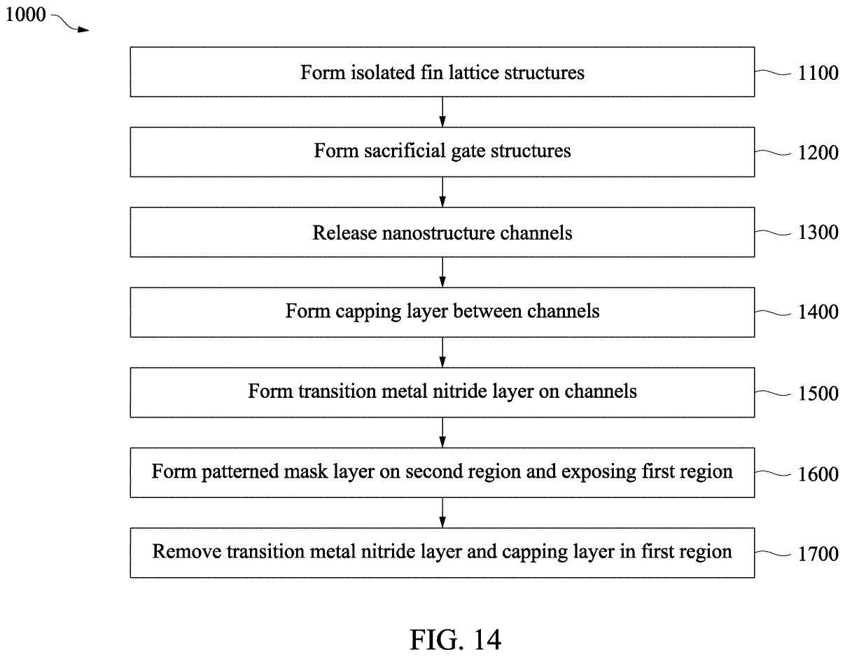

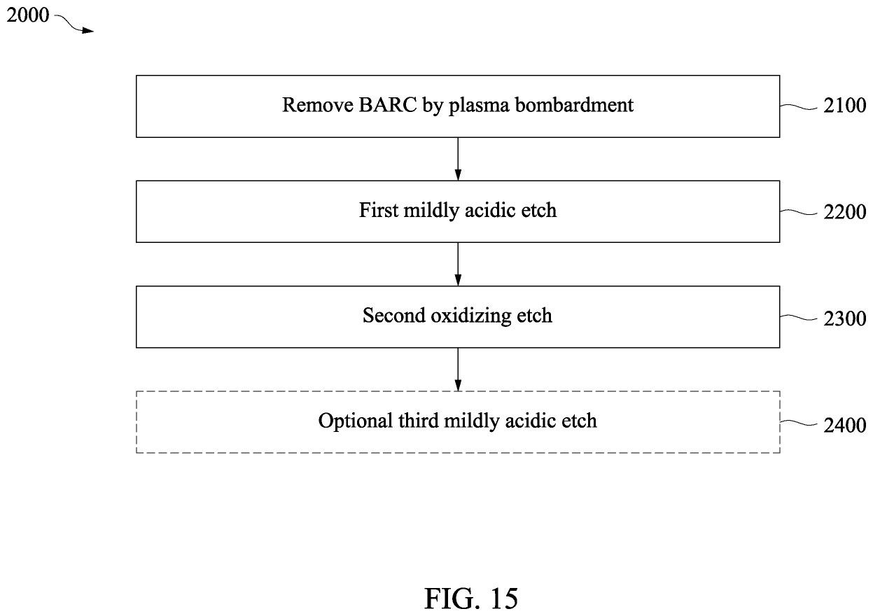

FIGS. 14 and 15 depict flowcharts of methods 1000, 2000 for forming an IC device or a portion thereof from a workpiece, according to one or more aspects of the present disclosure. Methods 1000, 2000 are merely examples and not intended to limit the present disclosure to what is explicitly illustrated in methods 1000, 2000. Additional acts can be provided before, during and after the methods 1000, 2000 and some acts described can be replaced, eliminated, or moved around for additional embodiments of the method. Not all acts are described herein in detail for reasons of simplicity. Methods 1000, 2000 are described below in conjunction with fragmentary perspective and/or cross-sectional views of a workpiece, shown in FIGS. 2A-13, at different stages of fabrication according to embodiments of methods 1000, 2000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

FIGS. 2A through 13 are views of intermediate stages in the manufacturing of FETs, such as nanostructure FETs, in accordance with some embodiments.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A, 21B, and 21C (collectively referred to as first semiconductor layers 21) and second semiconductor layers 23. In some embodiments, the first semiconductor layers 21 may be formed of a first semiconductor material suitable for n-type nano-FETs, such as silicon, silicon carbide, or the like, and the second semiconductor layers 23 may be formed of a second semiconductor material suitable for p-type nano-FETs, such as silicon germanium or the like. Each of the layers 21, 23 of the multi-layer stack 25 may be epitaxially grown using a process such as chemical vapor deposition (CVD), atomic layer deposition (ALD), vapor phase epitaxy (VPE), molecular beam epitaxy (MBE), or the like.

Three layers of each of the first semiconductor layers 21 and the second semiconductor layers 23 are illustrated. In some embodiments, the multi-layer stack 25 may include fewer or additional pairs of the first semiconductor layers 21 and the second semiconductor layers 23. Although the multi-layer stack 25 is illustrated as including a second semiconductor layer 23 as the bottommost layer, in some embodiments, the bottommost layer of the multi-layer stack 25 may be a first semiconductor layer 21.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nano-FETs. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nano-FETs.

In FIG. 3A and FIG. 3B, fins 32 are formed in the substrate 110 and nanostructures 22, 24 are formed in the multi-layer stack 25 corresponding to act 1100 of FIG. 14. In some embodiments, the nanostructures 22, 24 and the fins 32 may be formed by etching trenches in the multi-layer stack 25 and the substrate 110. The etching may be any acceptable etch process, such as a reactive ion etch (RIE), neutral beam etch (NBE), the like, or a combination thereof. The etching may be anisotropic. First nanostructures 22A, 22B, 22C (also referred to as “channels 22” below) are formed from the first semiconductor layers 21, and second nanostructures 24 are formed from the second semiconductor layers 23. Distance CD1 between adjacent fins 32 and nanostructures 22, 24 may be from about 18 nm to about 100 nm. A portion of the device 10 is illustrated in FIGS. 3A and 3B including two fins 32 for simplicity of illustration. The processes 1000, 2000 illustrated in FIGS. 14, 15 may be extended to any number of fins, and are not limited to the two fins 32 shown in FIGS. 3A-13.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIGS. 3A and 3B, isolation regions, features or structures 36, which may be shallow trench isolation (STI) regions, features or structures, are formed adjacent the fins 32. The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, a core material, such as those discussed above may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32 and the nanostructures 22, 24 substantially unaltered.

FIGS. 2A through 3B illustrate one embodiment (e.g., etch last) of forming the fins 32 and the nanostructures 22, 24. In some embodiments, the fins 32 and/or the nanostructures 22, 24 are epitaxially grown in trenches in a dielectric layer (e.g., etch first). The epitaxial structures may comprise the alternating semiconductor materials discussed above, such as the first semiconductor materials and the second semiconductor materials.

In FIG. 3A and FIG. 3B, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

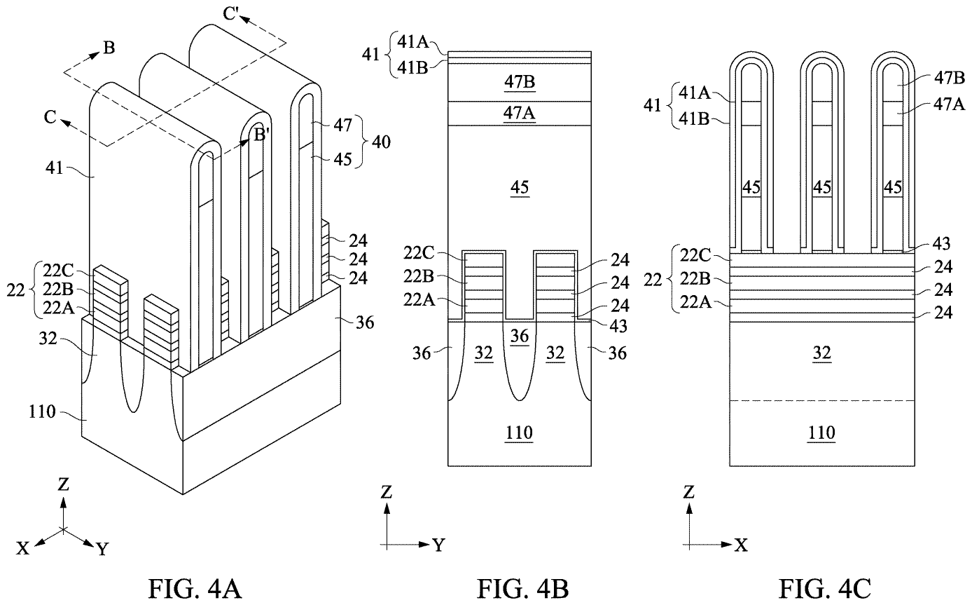

In FIGS. 4A-4C, dummy or sacrificial gate structures 40 are formed over the fins 32 and/or the nanostructures 22, 24, corresponding to act 1200 of FIG. 14. A dummy or sacrificial gate layer 45 is formed over the fins 32 and/or the nanostructures 22, 24. The dummy gate layer 45 may be or include materials that have a high etching selectivity relative to the isolation regions 36. The dummy gate layer 45 may be a conductive, semiconductive or non-conductive material and may be or include amorphous silicon, polycrystalline-silicon (polysilicon), poly-crystalline silicon-germanium (poly-SiGe), metallic nitrides, metallic silicides, metallic oxides, and metals. The dummy gate layer 45 may be deposited by physical vapor deposition (PVD), CVD, sputter deposition, or other techniques for depositing the selected material. A mask layer 47 is formed over the dummy gate layer 45, and may include, for example, silicon nitride, silicon oxynitride, or the like. In some embodiments, a gate dielectric layer 43 is formed before the dummy gate layer 45 between the dummy gate layer 45 and the fins 32 and/or the nanostructures 22, 24. In some embodiments, the mask layer 47 includes a first mask layer 47A in contact with the dummy gate layer 45, and a second mask layer 47B overlying and in contact with the first mask layer 47A. The first mask layer 47A may be or include the same or different material as that of the second mask layer 47B.

A spacer layer 41 is formed over sidewalls of the mask layer 47 and the dummy gate layer 45. The spacer layer 41 is or includes an insulating material, such as SiOCN, SiOC, SiCN or the like (or any of the materials described with reference to FIGS. 1A and 1B) and may have a single-layer structure or a multi-layer structure including a plurality of dielectric layers, in accordance with some embodiments. The spacer layer 41 may be formed by depositing a spacer material layer (not shown) over the mask layer 47 and the dummy gate layer 45. Portions of the spacer material layer between dummy gate structures 40 are removed using an anisotropic etching process, in accordance with some embodiments. In some embodiments, as shown in detail in FIGS. 4B, 4C, the spacer layer 41 includes a first spacer layer 41A in contact with the nanostructure 22C, the gate dielectric layer 43, the dummy gate layer 45 and the first and second mask layers 47A, 47B. A second spacer layer 41B of the spacer layer 41 may be in contact with the first spacer layer 41A. The first spacer layer 41A may be or include the same or different material as that of the second spacer layer 41B.

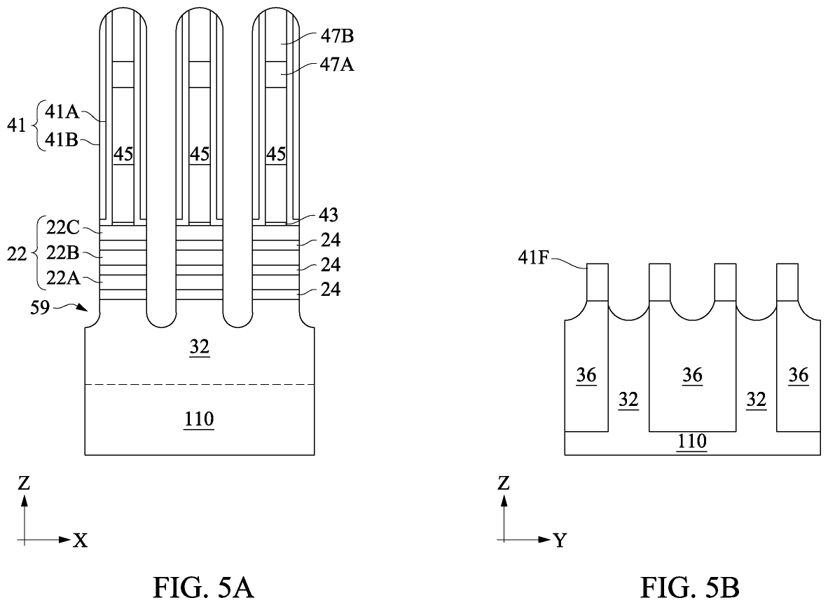

In FIGS. 5A and 5B, source/drain openings 59 are formed by performing an etching process to etch the portions of protruding fins 32 and/or nanostructures 22, 24 that are not covered by dummy gate structures 40. The recessing may be anisotropic, such that the portions of fins 32 directly underlying dummy gate structures 40 and the spacer layer 41 are protected and are not substantially etched. The top surfaces of the recessed fins 32 may be substantially coplanar with the top surfaces of the isolation regions 36, in accordance with some embodiments. The top surfaces of the recessed fins 32 may be lower than the top surfaces of the isolation regions 36, in accordance with some other embodiments, as depicted in FIG. 5B. FIG. 5A depicts three vertical stacks of nanostructures 22, 24 following the etching process for simplicity. In general, the etching process may be used to form fewer or additional vertical stacks of nanostructures 22, 24 over the fins 32 than those depicted. In some embodiments, the second mask layer 47B is exposed following the etching process, for example, due to removal of upper portions of the spacer layers 41A, 41B during the etching process. FIG. 5B depicts fin spacers 41F which are portions of the first and/or second spacer layers 41A, 41B that overlie the isolation regions 36 adjacent to respective fins 32.

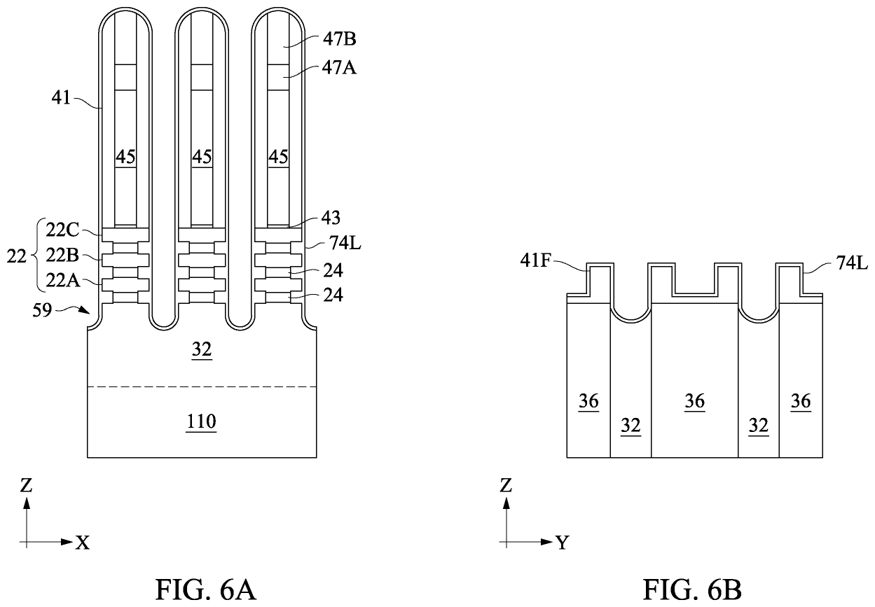

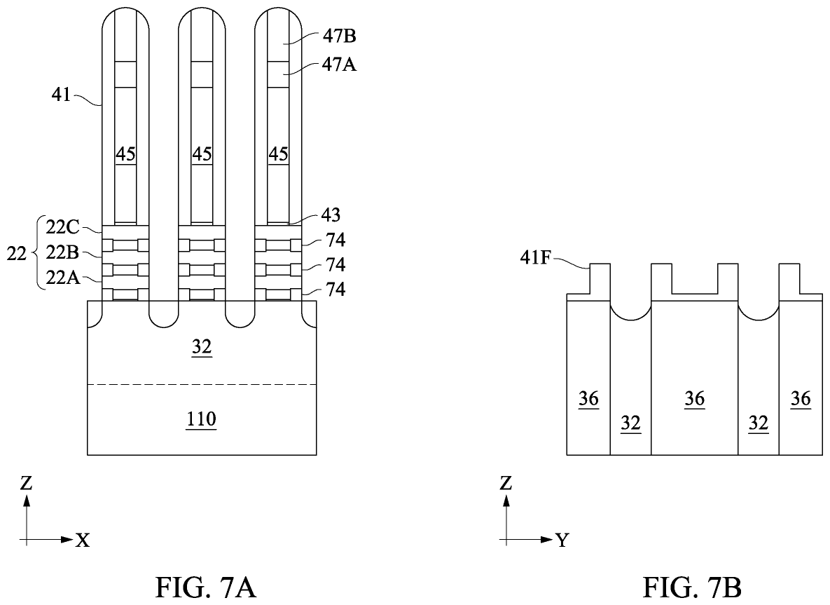

FIGS. 6A-7B depict formation of inner spacers 74 in accordance with various embodiments.

In FIGS. 6A, 6B, a selective etching process is performed to recess end portions of the nanostructures 24 exposed by openings in the spacer layer 41 without substantially attacking the nanostructures 22. After the selective etching process, recesses are formed in the nanostructures 24 at locations where the removed end portions used to be. Then, following formation of the recesses 64, an inner spacer layer 74L is formed to fill (partially or entirely) the recesses in the nanostructures 22 formed by the previous selective etching process. The inner spacer layer 74L may be a suitable dielectric material, such as silicon carbon nitride (SiCN), silicon oxycarbonitride (SiOCN), or the like, formed by a suitable deposition method such as PVD, CVD, ALD, or the like.

In FIGS. 7A and 7B, following formation of the inner spacer layer 74L, an etching process, such as an anisotropic etching process, is performed to remove portions of the inner spacer layer 74 disposed outside the recesses, for example, on sidewalls of the nanostructures 22 and the fins 32. The remaining portions of the inner spacer layer 74L (e.g., portions disposed inside the recesses in the nanostructures 24) form the inner spacers 74.

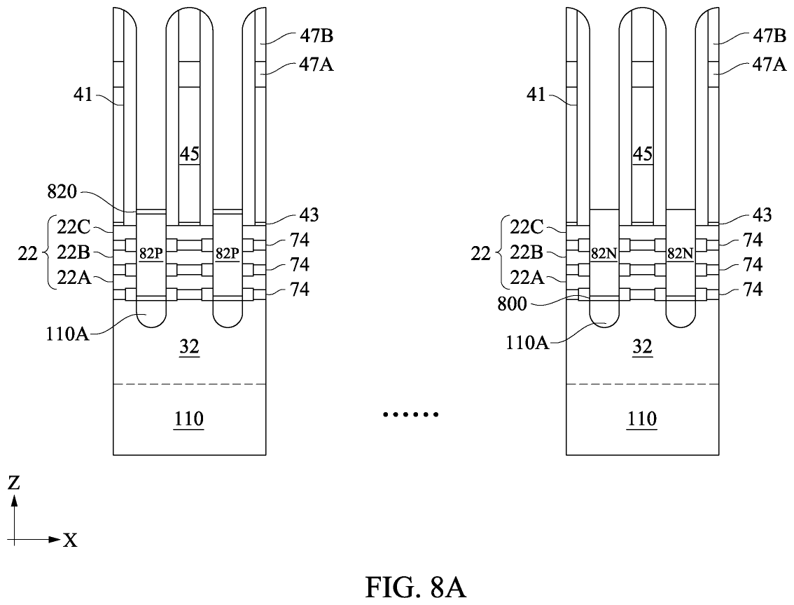

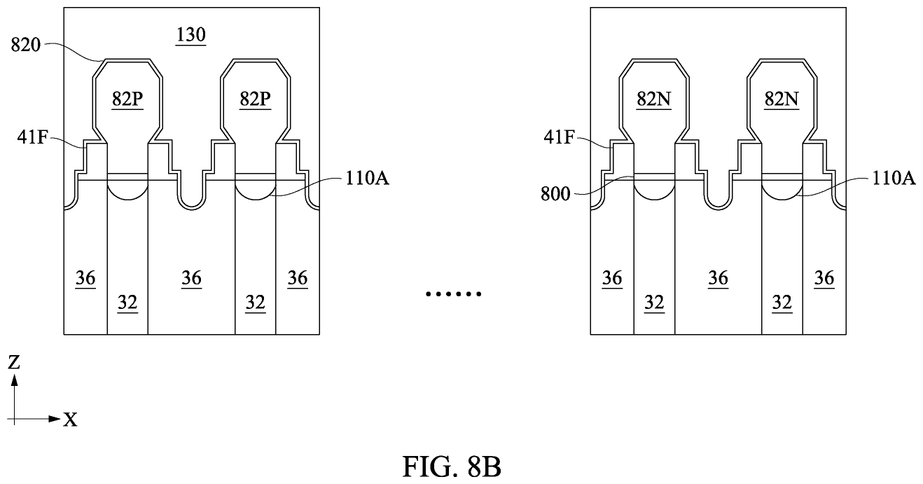

In FIG. 8A, a first semiconductor layer 110A is formed in the source/drain openings 59. The first semiconductor layer 110A is an undoped silicon layer in some embodiments that may be deposited or epitaxially grown on exposed surfaces of the fin 32. The deposition may include one or more operations, such as a CVD, which may be an Ultra-High Vacuum Chemical Vapor Deposition (UHV-CVD), which allows for improved control of deposition rate and purity of the first semiconductor layer 110A. In some embodiments, precursor gases containing silicon may be introduced into a processing chamber, and a reaction therebetween forms the silicon material, which deposits into the source/drain openings 59. In some embodiments, the first semiconductor layer 110A has an upper surface that is at a level substantially coplanar with an upper surface of the fin 32.

FIG. 8A also depicts formation of bottom insulators 800 and source/drain regions 82N, 82P or “source/drains 82N, 82P” in accordance with various embodiments. FIG. 8A depicts formation of p-type source/drains 82P and n-type source/drains 82N, which may be different from each other in some respects. Namely, devices including n-type source/drains 82N may benefit from inclusion of the bottom insulator 800, whereas devices including p-type source/drains 82P may benefit from exclusion of the bottom insulator 800.

In FIG. 8A, source/drain regions 82N, 82P are formed. In the illustrated embodiment, the source/drain regions 82P are epitaxially grown from epitaxial material(s). In some embodiments, the source/drain regions 82P exert stress in the respective channels 22A, 22B, 22C, thereby improving performance. The source/drain regions 82P are formed such that each dummy gate structure 40 is disposed between respective neighboring pairs of the source/drain regions 82P. In some embodiments, the spacer layer 41 separates the source/drain regions 82P from the dummy gate layer 45 by an appropriate lateral distance to prevent electrical bridging to subsequently formed gates of the resulting device. The source/drain regions 82P may be or include Si:B, Si:Ga, SiGe:B, SiGe:B: Ga, SiGe:Sn, SiGe:B:Sn or the like. The source/drain regions 82P may exert a compressive strain in the channel regions. The source/drain regions 82N, 82P may have surfaces raised from respective surfaces of the first semiconductor layer 110A and may have facets. Neighboring source/drain regions 82P may merge in some embodiments to form a singular source/drain region 82P adjacent two neighboring fins 32.

In the illustrated embodiment, following formation of the source/drain regions 82P, the optional bottom insulator 800 may be formed. Formation of the bottom insulator 800 may include a suitable deposition operation, such as an LPCVD, PECVD, ALD, or the like. The bottom insulator 800 may be or include SiN or another suitable dielectric material. Thickness of the bottom insulator 800 may be in a range of about 2 nm to about 4 nm. During formation of the bottom insulator 800, a dielectric layer 820 may be formed on the upper surface of the source/drain region 82P. The dielectric layer 820 may have the same composition (e.g., SiN) and thickness as those of the bottom insulator 800. The bottom insulator 800 may be present on the first semiconductor layer 110A, such as in direct contact with an upper surface of the first semiconductor layer 110A. Side surfaces of the bottom insulator 800 may be in direct contact with side surfaces of a bottommost inner spacer of the inner spacers 74.

Following formation of the bottom insulator 800, the source/drain regions 82N are epitaxially grown from epitaxial material(s). Due to the bottom insulator 800, the source/drain regions 82N may grow from the channels 22 without growing from the first semiconductor layer 110A. In some embodiments, the source/drain regions 82N exert stress in the respective channels 22A, 22B, 22C, thereby improving performance. The source/drain regions 82N are formed such that each dummy gate structure 40 is disposed between respective neighboring pairs of the source/drain regions 82N. In some embodiments, the spacer layer 41 separates the source/drain regions 82N from the dummy gate layer 45 by an appropriate lateral distance to prevent electrical bridging to subsequently formed gates of the resulting device. The source/drain regions 82N may be or include SiP, SiAs, SiSb, SiPAs, SiP:As:Sb or the like. The source/drain regions 82N may exert a tensile strain in the channel regions due to presence of the bottom insulator 800. The source/drain regions 82N may have surfaces raised from respective surfaces of the fins 32 and may have facets. Neighboring source/drain regions 82N may merge in some embodiments to form a singular source/drain region 82N adjacent two neighboring fins 32.

In some embodiments, the bottom insulator 800 and dielectric layer 820 are not formed. In such embodiments, the source/drain regions 82N, 82P grow from the first semiconductor layer 110A and the nanosheets 22 and are in direct contact with the first semiconductor layer 110A.

In FIG. 8B, following formation of the source/drain regions 82N, 82P, the ILD 130 may be formed covering the source/drain regions 82N, 82P and abutting the spacer layer 41. In some embodiments, the ESL 131 is formed prior to forming the ILD 130. The ESL 131 may be formed by depositing a conformal thin layer of a dielectric material different from that of the ILD 130, such as one or more of SiN, SiCN, SiC, SiOC, SiOCN, HfO2, ZrO2, ZrAlOx, HfAlOx, HfSiOx, Al2O3, or other suitable material. Following deposition of the ESL 131, the ILD 130 may be deposited by a suitable process, such as a blanket deposition process, including PVD, CVD, ALD, or the like. The material of the ILD 130 may include silicon dioxide or a low-k dielectric material (e.g., a material having a dielectric constant (k-value) lower than the k-value (about 3.9) of silicon dioxide). The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOxCy), Spin-On-Glass (SOG) or a combination thereof. The ILD 130 may be deposited by spin-on coating, CVD, Flowable CVD (FCVD), PECVD, PVD, or another deposition process.

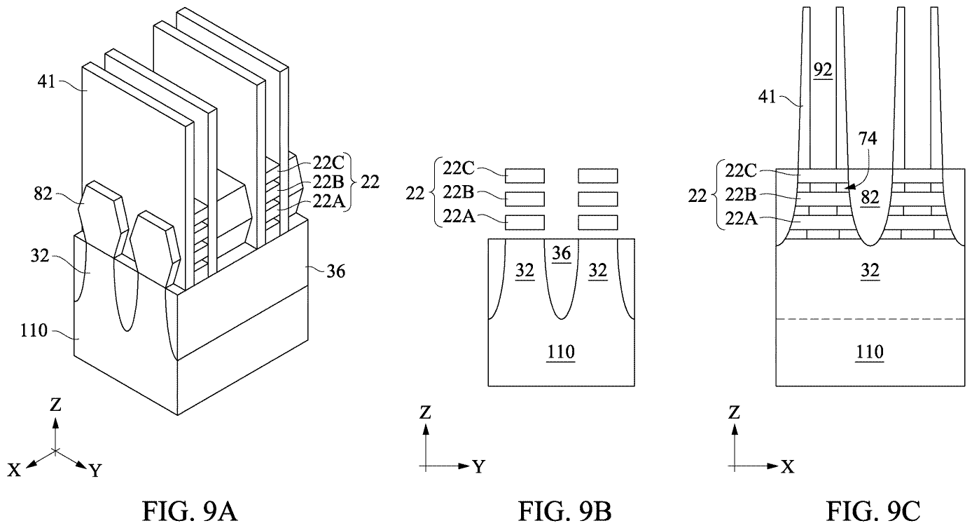

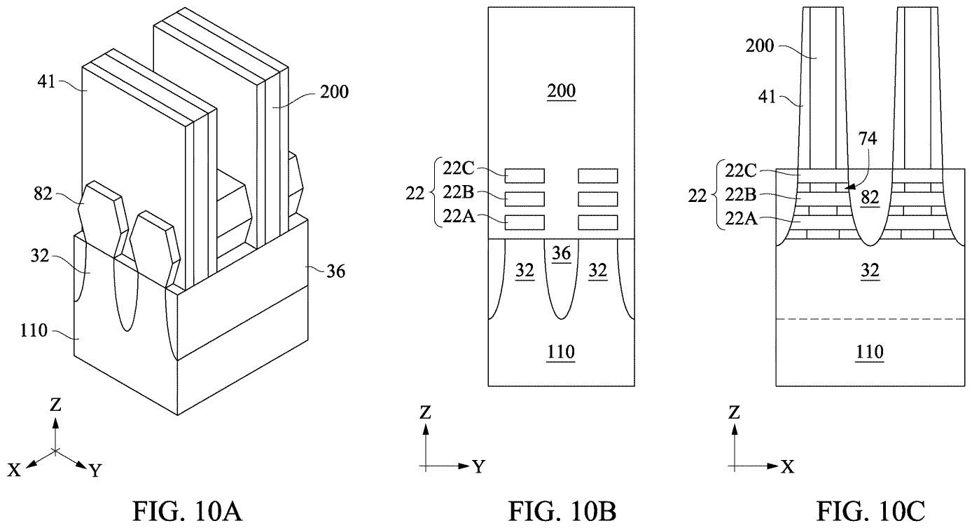

In FIGS. 9A-10C, following formation of the source/drains 82N, 82P, the ESL 131 and the ILD 130, active gate structures 200 may be formed. A planarization process, such as a chemical mechanical polishing (CMP) process, is performed on the ILD 130 and the ESL 131. The hard masks 47A, 47B and portions of the gate spacers 41 are also removed in the planarization process. After the planarization process, the dummy gate layers 45 are exposed. The top surfaces of the ILD 130 and the ESL 131 may be coplanar with the top surfaces of the dummy gate layers 45 and the gate spacers 41.

Next, as depicted in FIGS. 9A-9C, the dummy gate layer 45 is removed in an etching process, so that openings 92 are formed, corresponding to act 1400 of FIG. 14. In some embodiments, the dummy gate layer 45 is removed by an anisotropic dry etch process. For example, the etching process may include a dry etch process using reaction gas(es) that selectively etch the dummy gate layer 45 without etching the spacer layer 41. The dummy gate dielectric 43, when present, may be used as an etch stop layer when the dummy gate layer 45 is etched. The dummy gate dielectric 43 may then be removed after the removal of the dummy gate layer 45.

The nanostructures 24 are removed to release the nanostructures 22. After the nanostructures 24 are removed, the nanostructures 22 form a plurality of nanosheets that extend horizontally (e.g., parallel to a major upper surface of the substrate 110). In some embodiments, the nanostructures 24 are removed by a selective etching process using an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like.

In some embodiments, the nanostructures 24 are removed and the nanostructures 22 are patterned to form channel regions of both PFETs and NFETs. However, in some embodiments the nanostructures 24 may be removed and the nanostructures 22 may be patterned to form channel regions of NFETs, and nanostructures 22 may be removed and the nanostructures 24 may be patterned to form channel regions of PFETs. In some embodiments, the nanostructures 22 may be removed and the nanostructures 24 may be patterned to form channel regions of NFETs, and the nanostructures 24 may be removed and the nanostructures 22 may be patterned to form channel regions of PFETs. In some embodiments, the nanostructures 22 may be removed and the nanostructures 24 may be patterned to form channel regions of both PFETs and NFETs.

In some embodiments, the nanosheets 22 are reshaped (e.g., thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction.

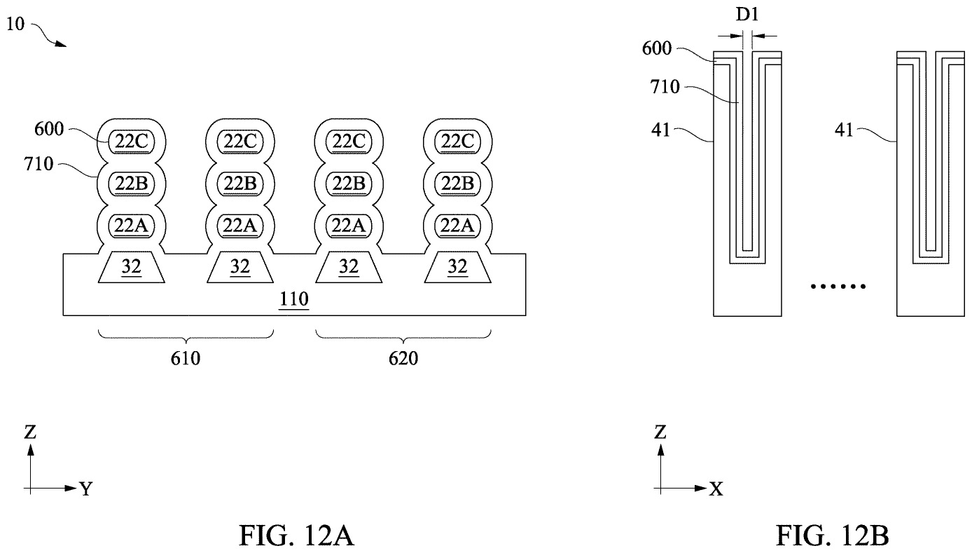

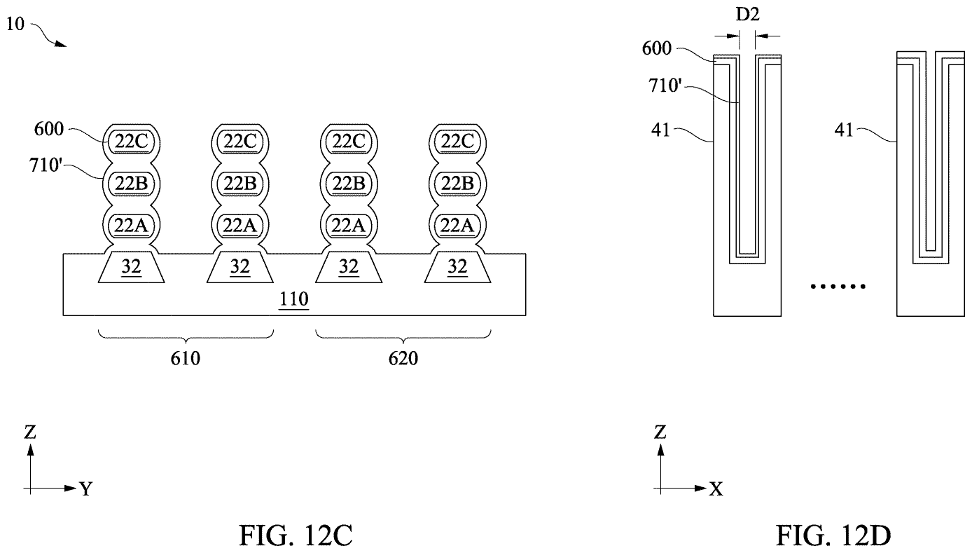

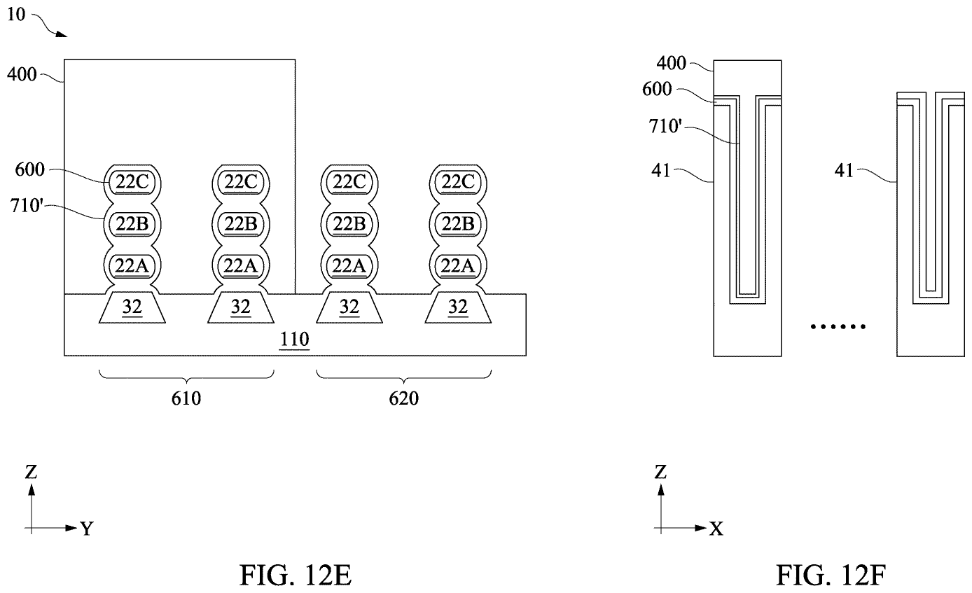

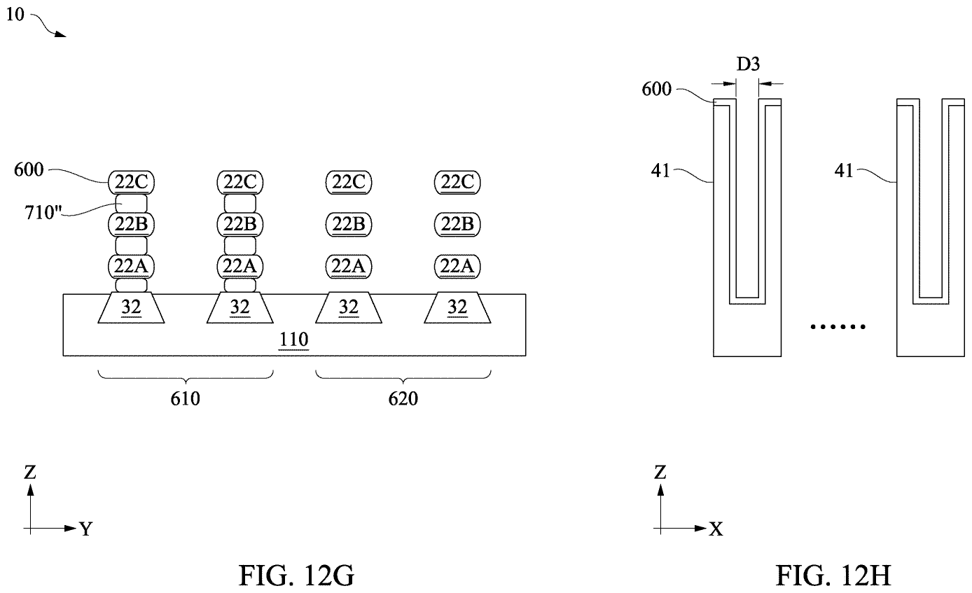

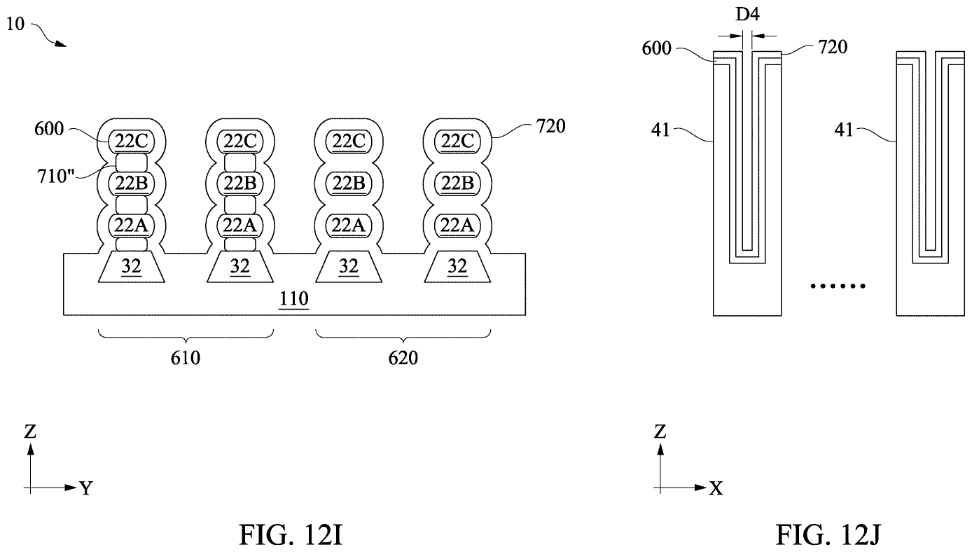

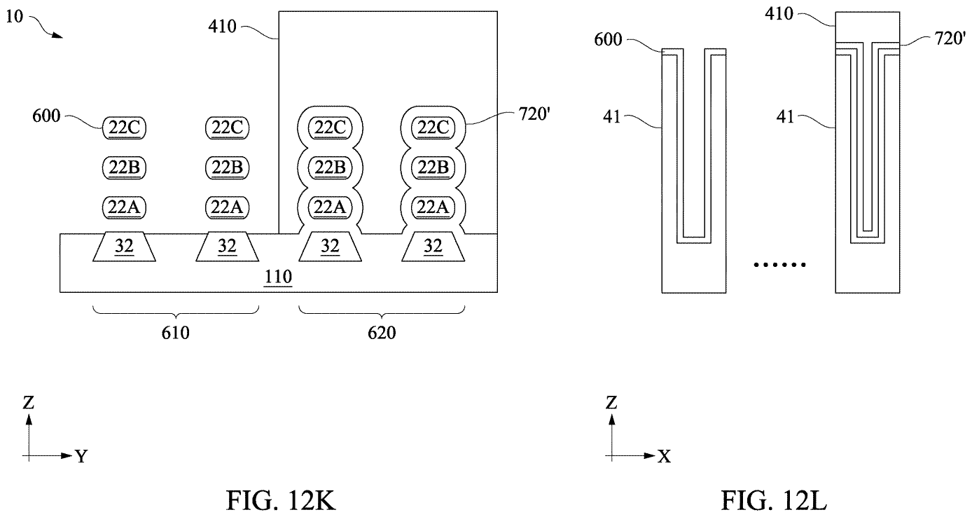

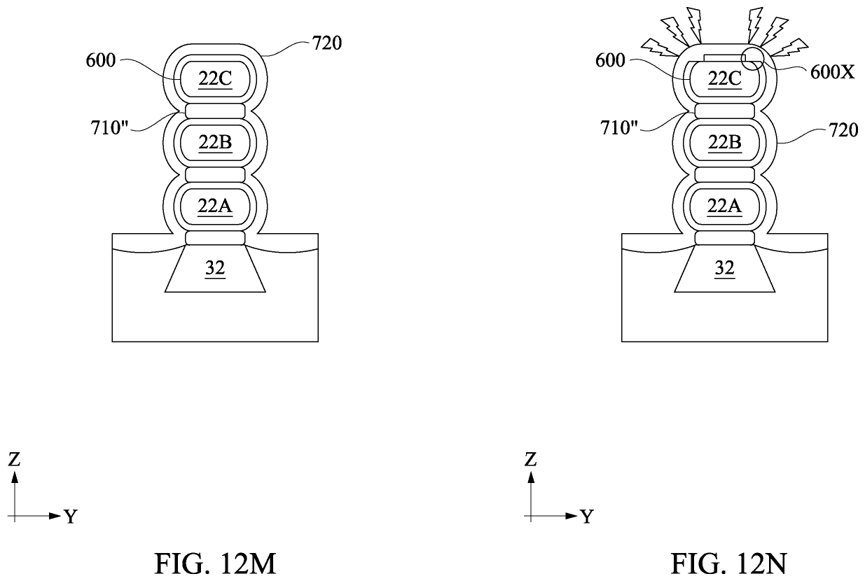

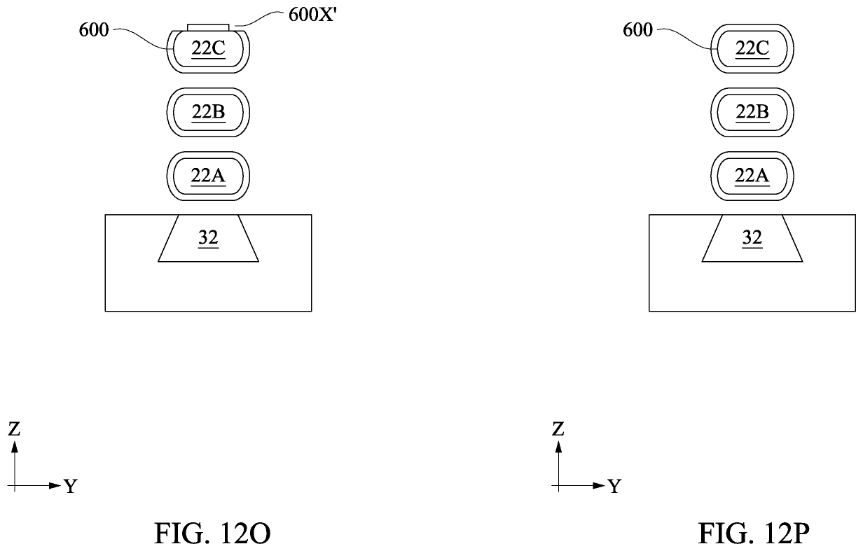

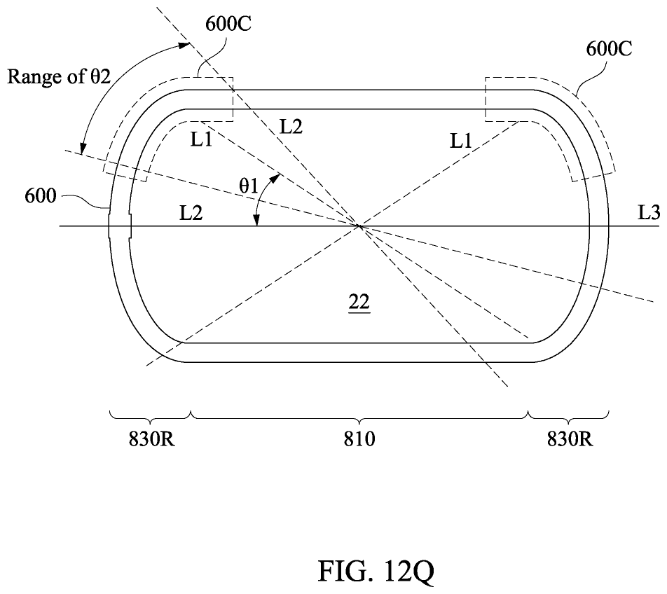

Then, replacement gates 200 are formed. The replacement gates 200 may be referred to as active gates 200 or gate structures 200. The gate structures 200 may be formed by a series of deposition operations, such as ALD cycles, that deposit the various layers of the gate structure 200 in the openings, described below with reference to FIG. 11. Formation of the gate structure 200 is described in detail with reference to FIG. 11 to provide context for understanding the embodiments described with reference to FIGS. 12A-12Q.

FIG. 11 is a detailed view of a portion of the gate structure 200. The gate structure 200 generally includes the interfacial layer (IL, or “first IL” below) 210, at least one gate dielectric layer 600, the work function metal layer 900, and the gate fill layer 290. In some embodiments, each replacement gate 200 further includes at least one of a second interfacial layer 240 or a second work function layer 700.

With reference to FIG. 11, in some embodiments, the first IL 210 includes an oxide of the semiconductor material of the substrate 110, e.g., silicon oxide. In other embodiments, the first IL 210 may include another suitable type of dielectric material. The first IL 210 has a thickness in a range between about 5 angstroms and about 50 angstroms.

Still referring to FIG. 11, the gate dielectric layer 600 is formed over the first IL 210. In some embodiments, an atomic layer deposition (ALD) process is used to form the gate dielectric layer 600 to control thickness of the deposited gate dielectric layer 600 with precision. In some embodiments, the ALD process is performed using between about 40 and 80 deposition cycles, at a temperature range between about 200 degrees Celsius and about 300 degrees Celsius. In some embodiments, the ALD process uses HfCl4 and/or H2O as precursors. Such an ALD process may form the first gate dielectric layer 220 to have a thickness in a range between about 10 angstroms and about 100 angstroms.

In some embodiments, the gate dielectric layer 600 includes a high-k dielectric material, which may refer to dielectric materials having a high dielectric constant that is greater than a dielectric constant of silicon oxide (k≈3.9). Exemplary high-k dielectric materials include HfO₂, HfSiO, HfSiON, HfTaO, HfTiO, HfZrO, ZrO₂, Ta₂O₅, or combinations thereof. In other embodiments, the gate dielectric layer 600 may include a non-high-k dielectric material such as silicon oxide. In some embodiments, the gate dielectric layer 600 includes more than one high-k dielectric layer, of which at least one includes dopants, such as lanthanum, magnesium, yttrium, or the like, which may be driven in by an annealing process to modify threshold voltage of the nanostructure devices 20A, 20B.

With further reference to FIG. 11, an optional second IL 240 is formed on the gate dielectric layer 600, and the second work function layer 700 is formed on the second IL 240. The second IL 240 promotes better metal gate adhesion on the gate dielectric layer 600. In many embodiments, the second IL 240 further provides improved thermal stability for the gate structure 200 and serves to limit diffusion of metallic impurities from the work function metal layer 900 and/or the work function barrier layer 700 into the gate dielectric layer 600. In some embodiments, formation of the second IL 240 is accomplished by first depositing a high-k capping layer (not illustrated for simplicity) on the gate dielectric layer 600. The high-k capping layer comprises one or more of the following: HfSiON, HfTaO, HfTiO, HfTaO, HfAlON, HfZrO, or other suitable materials, in various embodiments. In one embodiment, the high-k capping layer comprises titanium silicon nitride (TiSiN). In some embodiments, the high-k capping layer is deposited by an ALD using about 40 to about 100 cycles at a temperature of about 400 degrees C to about 450 degrees C. A thermal anneal is then performed to form the second IL 240, which may be or comprise TiSiNO, in some embodiments. Following formation of the second IL 240 by thermal anneal, an atomic layer etch (ALE) with artificial intelligence (AI) control may be performed in cycles to remove the high-k capping layer while substantially not removing the second IL 240. Each cycle may include a first pulse of WCl₅, followed by an Ar purge, followed by a second pulse of O₂, followed by another Ar purge. The high-k capping layer is removed to increase gate fill window for further multiple threshold voltage tuning by metal gate patterning.

Further in FIG. 11, after forming the second IL 240 and removing the high-k capping layer, the work function barrier layer 700 is optionally formed on the gate structure 200, in accordance with some embodiments. The work function barrier layer 700 is or comprises a metal nitride, such as TiN, WN, MoN, TaN, or the like. In a specific embodiment, the work function barrier layer 700 is TiN. The work function barrier layer 700 may have thickness ranging from about 5 A to about 20 A. Inclusion of the work function barrier layer 700 provides additional threshold voltage tuning flexibility. In general, the work function barrier layer 700 increases the threshold voltage for NFET transistor devices, and decreases the threshold voltage (magnitude) for PFET transistor devices.

The work function metal layer 900, which may include at least one of an N-type work function metal layer, an in-situ capping layer, or an oxygen blocking layer, is formed on the work function barrier layer 700, in some embodiments. The N-type work function metal layer is or comprises an N-type metal material, such as TiAlC, TiAl, TaAlC, TaAl, or the like. The N-type work function metal layer may be formed by one or more deposition methods, such as CVD, PVD, ALD, plating, and/or other suitable methods, and has a thickness between about 10 A and 20 A. The in-situ capping layer is formed on the N-type work function metal layer. In some embodiments, the in-situ capping layer is or comprises TiN, TiSiN, TaN, or another suitable material, and has a thickness between about 10 A and 20 A. The oxygen blocking layer is formed on the in-situ capping layer to prevent oxygen diffusion into the N-type work function metal layer, which would cause an undesirable shift in the threshold voltage. The oxygen blocking layer is formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the oxygen blocking layer is formed using ALD and has a thickness between about 10 A and about 20 A.

FIG. 11 further illustrates the metal core layer 290. In some embodiments, a glue layer (not separately illustrated) is formed between the oxygen blocking layer of the work function metal layer and the metal core layer 290. The glue layer may promote and/or enhance the adhesion between the metal core layer 290 and the work function metal layer 900. In some embodiments, the glue layer may be formed of a metal nitride, such as TiN, TaN, MoN, WN, or another suitable material, using ALD. In some embodiments, thickness of the glue layer is between about 10 A and about 25 A. The metal core layer 290 may be formed on the glue layer, and may include a conductive material such as tungsten, cobalt, ruthenium, iridium, molybdenum, copper, aluminum, or combinations thereof. In some embodiments, the metal core layer 290 may be deposited using methods such as CVD, PVD, plating, and/or other suitable processes. In some embodiments, a seam 510, which may be an air gap, is formed in the metal core layer 290 vertically between the channels 22A, 22B, 22C. In some embodiments, the metal core layer 290 is conformally deposited on the work function metal layer 900. The seam 510 may form due to sidewall deposited film merging during the conformal deposition. In some embodiments, the seam 510 is not present between the neighboring channels 22A, 22B, 22C.

In some embodiments, one or more of metal layers including the core layer 290 and the work function layers 700, 900 in PFET devices can include Ti, Al, Zn, W, Nb, Co and the like and total thickness of the combination of metal layers on the gate dielectric layer 600 may be in a range of about 0.5 nm to about 20 nm. In some embodiments, one or more of metal layers including the core layer 290 and the work function layers 700, 900 in NFET devices can include Ti and/or Al and the like and total thickness of the combination of metal layers on the gate dielectric layer 600 may be in a range of about 0.5 nm to about 20 nm.

FIGS. 12A-12Q are cross-sectional side views of formation of a portion of the gate structure 200 of the IC device 10 in accordance with various embodiments. The dielectric layer 600, such as HfO2, SiO2, and ZrO2, is beneficial for improving turning on of a field effect transistor, such as the nanostructure transistor 20A. Quality of the dielectric layer 600, including thickness, vacancies, heterogeneous atom contamination and the like can degrade threshold voltage (Vt), channel resistance (Rch), ring performance (RO%), time-dependent-dielectric-breakdown (TDDB) and maximum voltage degradation, especially after long periods of operation, e.g., about ten years. In devices that include nanosheets such as described with reference to FIGS. 1A-11, dielectrics at corners of nanosheets 22 undergo dry bombardment and may experience a stress concentration effect that degrades film quality. Then, a subsequent wet chemical etch or clean for metal removal may damage the dielectric layer 600.

In the embodiments described with reference to FIGS. 12A-12Q, a high-selectivity wet-etching process simultaneously etches metal (e.g., the work function layers 700, 900) without substantially removing the dielectric layer 600.

In FIGS. 12A, 12B, following formation of the IL 210 and the high-k dielectric layer 600, a capping layer 710 may be formed on and wrapping around the channels 22A, 22B, 22C and the fins 32, corresponding to act 1400 of FIG. 14. The capping layer 710 may wrap around the channels 22 on all sides in the cross-sectional profile along the YZ plane, as depicted in FIG. 12A and may partially wrap around the fins 32. The capping layer 710 may be or include a dielectric material, such as SiN, SiCN, SiC, SiOC, SiOCN, HfO2, ZrO2, ZrAlOx, HfAlOx, HfSiOx, Al₂O₃ or the like. In some embodiments, the capping layer 710 is an Al₂O₃ layer. The capping layer 710 may be deposited by a suitable deposition process, such as a PVD, CVD, ALD or the like. Thickness of the capping layer 710 may be in a range of about 1 nm to about 5 nm, such as about 3 nm. Following the deposition, a first gap D1 may be present between adjacent side surfaces of the capping layer 710. The first gap D1 may be in a range of about 1 nm to about 6 nm, such as about 3.5 nm. A later process deposits a thin layer of a transition metal nitride, such as TiN, TaN, onto the channels 22. Forming the capping layer 710 is beneficial to prevent the transition metal nitride layer from filling gaps between vertically adjacent channels 22, such as the channel 22A and the channel 22B.

In FIGS. 12C, 12D, following formation of the capping layer 710, a thinned capping layer 710′ is formed by thinning the capping layer 710. Thinning the capping layer 710 to form the thinned capping layer 710′ can be beneficial to enlarge poly spacing, such as from about 3.5 nm (e.g., first gap D1) to about 6.5 nm or more (e.g., second gap D2). In some embodiments, the second gap D2 is in a range of about 3 nm to about 10 nm, such as about 6 nm. The second gap D2 is larger than the first gap D1. Thinning the capping layer 710 may include one or more etching operations, which may be isotropic wet etch operations. The thinned capping layer 710′ may have thickness that is in a range of about 1 nm to about 2 nm, such as about 1.7 nm, which is about or slightly more than half the thickness of the capping layer 710. In some embodiments, thinning of the capping layer 710 to form the thinned capping layer 710′ is not performed.

In FIGS. 12E, 12F, following optional thinning of the capping layer 710 to form the thinned capping layer 710', a patterned mask 400 is formed that protects a first region 610 of the device 10 while exposing a second region 620 of the device 10. In some embodiments, the patterned mask 400 is or includes a bottom antireflective coating (BARC) layer 400. Prior to forming the BARC layer 400, the surface of the device 10 may be cleaned to remove particles or unwanted materials that can interfere with the BARC deposition. Then, the BARC layer 400 may be deposited over the entire surface of the device 10, covering the stacks of nanosheets 22 and gaps in between. The BARC layer 400 may be deposited via spin coating or chemical vapor deposition (CVD). After deposition, the BARC layer 400 may be baked to remove solvent and improve properties thereof. Then, a photoresist layer may be applied on top of the BARC layer 400. A pattern is then transferred onto the photoresist layer via a photolithography process that involves exposing the photoresist layer to light reflected from a mask that has the selected pattern. The exposed photoresist layer is developed, washing away either the exposed or unexposed areas (depending on whether a positive or negative photoresist is used), exposing the underlying BARC layer 400 in a pattern that matches the mask. Then, the exposed BARC areas are etched away, for example by a plasma etch process. The etching selectively removes the BARC where the photoresist has been washed away, transferring the pattern from the photoresist to the BARC layer 400. After etching, remaining photoresist is stripped away, leaving behind a patterned BARC layer 400 that corresponds to the selected design.

In FIGS. 12E, 12F, portions of the thinned capping layer 710′ (or the capping layer 710 when not thinned) that are exposed by the BARC layer 400 are removed via one or more suitable etching operations. Removal of the thinned capping layer 710′ may be in the second region 620, which may be a PFET region of the device 10. The removal may be via an etching operation, such as an isotropic wet etch, that is selective to material of the thinned capping layer 710′ without substantially attacking the gate dielectric layer 600 and/or the substrate 110. The removal may completely remove the thinned capping layer 710 from surfaces of the nanosheets 22 in the second region 620, such that the gate dielectric layer 600 is completely exposed in the second region 620.

In FIGS. 12G, 12H, following removal of the thinned capping layer 710′ or the capping layer 710 in the second region 620, the thinned capping layer 710′ or the capping layer 710 is thinned to remove portions thereof that are on an upper surface of the topmost nanosheet 22C and on side surfaces or sidewalls of the nanosheets 22A, 22B, 22C and the fin 32. This results in the dummy plugs 710″ that are positioned between adjacent nanosheets 22 (e.g., the nanosheets 22A, 22B) and between the bottommost nanosheet 22A and the fin 32. The dummy plugs 710″ may have width in the Y-axis direction that is less than width of the nanosheets 22A, 22B, 22C in the Y-axis direction. Each of the dummy plugs 710″ may extend from the gate dielectric layer 600 on one of the nanosheets 22 to the gate dielectric layer 600 on another of the nanosheets 22 or the fin 32 adjacent to the one. The dummy plugs 710″ may be in direct contact with the gate dielectric layer 600 and may have side surfaces that are exposed. Following formation of the dummy plugs 710″ by removing the portions described, a third gap D3 is present between adjacent sidewalls, as depicted in FIG. 12H. The third gap D3 may be in a range of about 5 nm to about 15 nm, such as about 10 nm. The third gap D3 exceeds the second gap D2 and the first gap D1, which further increases poly spacing.

In some embodiments, removal of the capping layer 710 and/or the thinned capping layer 710′ may result in some slight removal of the underlying dielectric layer 600. As such, after the etching operation described with reference to FIGS. 12G, 12H, exposed regions of the gate dielectric layer 600 in the first region 610 may have thickness that is slightly less than protected regions of the gate dielectric layer 600 in the first regions 610 (e.g., regions in direct contact with the dummy plugs 710″) and that slightly exceeds thickness of the gate dielectric layer 600 in the second region 620. In some embodiments, the thickness of the gate dielectric layer 600 in the second region 620 (e.g., around the nanosheets 22) may be substantially uniform whereas that of the gate dielectric layer 600 in the first region 610 may be non-uniform.

In FIGS. 12I, 12J, following formation of the dummy plugs 710″, a transition metal nitride layer 720 (or “layer 720”), such as a TiN layer, is formed on exposed surfaces of the gate dielectric layer 600, the dummy plugs 710″ and the substrate 110, corresponding to act 1500 of FIG. 14. The layer 720 may be deposited on the surfaces by a suitable deposition operation, which may be a PVD, CVD, ALD or the like. Thickness of the layer 720 may be in a range of about 1 nm to about 5 nm, such as about 3 nm. Following deposition of the layer 720, a fourth gap D4 may be present that is smaller than the third gap D3 and is in a range of about 2 nm to about 6 nm, such as about 4 nm. Due to the dummy plugs 710″, the transition metal nitride layer 720 in the first region 610 may not wrap completely around the nanosheets 22 and fill the gaps therebetween. In the second region 620, the transition metal nitride layer 720 may wrap completely around the nanosheets 22 and fill the gaps therebetween. The layer 720 will be removed in the first region 610 in a later operation. Having the dummy plugs 710″ in the gaps between the nanosheets 22 instead of the layer 720 makes it easier to clear the gaps of material prior to forming layers of the gate structure 200. Namely, it may be easier to remove the dummy plugs 710″ from between adjacent nanostructures 22 than it is to remove the transition metal nitride layer 720 from between the adjacent nanostructures 22.

In FIGS. 12K, 12L, following formation of the transition metal nitride layer 720, a second patterned mask layer 410 is formed that covers the second region 620 while exposing the first region 610, corresponding to act 1600 of FIG. 14. As such, the layer 720 is exposed in the first region 610. In some embodiments, the second patterned mask layer 410 is or includes a BARC layer. Then, the layer 720 is removed in the first region 610 leaving a patterned layer 720′ in the second region 620 and exposing portions of the gate dielectric layer 610 outside the dummy plugs 710″. The layer 720 may be removed by a suitable etching operation, such as a wet etch. Following removal of the layer 720, remaining portions of the gate dielectric layer 600 in the first region 610 are exposed by removing the dummy plugs 710″, such that the gate dielectric layer 600 is fully exposed in the first region 610. As discussed with reference to FIGS. 12G and 12H, due to differences in number and sequence of etching operations performed on the gate dielectric layer 600 in the first region 610, as well as presence of the dummy plugs 710″, thickness of the gate dielectric layer 600 in the first region 610 may be non-uniform. For example, thickness of portions of the gate dielectric layer 600 that were in direct contact with the dummy plugs 710″ may slightly exceed thickness of other portions of the gate dielectric layer 600 that were exposed by the dummy plugs 710″.

FIGS. 12M, 12N, 12O and 12P are cross-sectional views of a single stack of nanostructures 22A, 22B, 22C of the first region 610 following a removal process that removes the layer 720 and the dummy plugs 710″ as described with reference to FIGS. 12K, 12L and FIG. 15.

In FIG. 12M, the layer 720 is exposed. For example, the layer 720 may be positioned in the first region 610 while the second region 620 is protected by the second patterned mask 410. When the transition metal nitride layer 720 is deposited on the gate dielectric layer 600, some intermixing between the layers 720, 600 occurs, which may be referred to as natural intermixing.

Then, in FIG. 12N, a plasma etching or plasma bombarding is performed to form the second patterned mask layer 410, corresponding to act 2100 of FIG. 15. Namely, a BARC layer may be formed on the first and second regions 610, 620. Then a patterned photoresist layer may be formed on the BARC layer. Exposed portions of the BARC layer, such as in the first region, are then removed via a plasma etch process, which may include plasma bombardment, which is a process where a suitable gas is introduced and ionized in a vacuum chamber, creating a plasma. The ionization occurs when energy, usually from radio-frequency (RF) power, is applied, leading to the formation of positively charged ions and free electrons. The ions are then accelerated by an electric field towards the BARC layer, where they energetically collide with the surface thereof. These collisions can physically knock off atoms (physical sputtering), react chemically to form volatile byproducts, or cause radiation damage to the material. The intensity and effects of the bombardment are influenced by factors such as the power of the RF source, chamber pressure, and etching duration. The process may be selective and anisotropic, removing the BARC efficiently while reducing damage to underlying or adjacent materials, which can be beneficial for maintaining precise feature dimensions.

The inventors have realized that, although plasma bombardment can reduce damage to underlying or adjacent materials, such as the gate dielectric layer 600, it is not sufficient in all respects. Namely, as depicted in FIG. 12N, in corner regions 600X of the gate dielectric layer 600 wrapped around at least the uppermost channel 22C, deep intermixing between the gate dielectric layer 600 and the transition metal nitride layer 720 may occur. In some instances, the gate dielectric layer 600 wrapped around the channel 22B immediately below the uppermost channel 22C may also have deep intermixing in corner regions thereof.

In FIG. 12O, one or more wet etch operations are performed that remove the layer 720 and the dummy plugs 710″, resulting in the structure shown and corresponding to act 1700 of FIG. 14. In the corner regions 600X, voids 600X′ may be formed by removal of material of the gate dielectric layer 600 during the wet etch operation(s). The voids 600X′ can result in degradation of threshold voltage Vt, channel resistance Rch, ring performance RO %, time-dependent-dielectric-breakdown (TDDB), maximum voltage and the like. The inventors have realized that performing one or more etches that use a basic or first etchant, such as an etchant including NH4OH:H2O2:H20 in a ratio of about 1:5:25 can result in formation of the voids 600X'. In some embodiments, instead of using the basic etchant, a slightly acidic or mildly acidic or second etchant is used to remove the layer 720, which results in little to no removal of the gate dielectric layer 600 in the corner regions 600X, thereby reducing the formation of voids 600X′ and improving one or more of the performance metrics just listed. In some embodiments, a third etchant, such as H2O2:H2O in a ratio of about 1:5 may be included in the one or more wet etch operations.

In some embodiments, a first etch operation is performed, followed by a second etch operation, followed by an optional third etch operation.

Following removal of the BARC 410 and exposure of the first region 610, the first etch operation may be performed, corresponding to act 2200 of FIG. 15. The first etch operation may be a wet etch operation that includes the second etchant. In some embodiments, the second etchant includes HCl:H2O2: H2O in a ratio of about 1:10:50. In some embodiments, the second etchant includes HCl in a concentration in a range of about 0.1 wt % to about 50 wt %. In some embodiments, the second etchant includes an organic acid in a concentration in a range of about 0.1 wt % to about 50 wt %. In some embodiments, the organic acid includes one or more of citric acid, formic acid, oxalic acid, or the like. The first etch operation may remove most of the layer 720, such as at least about 90% of the layer 720, at least about 95% of the layer 720, at least about 99% of the layer 720 or another suitable amount of the layer 720.

The second etch operation follows the first etch operation, corresponding to act 2300 of FIG. 15, and may include an oxidizing mixture as the third etchant, such as H2O2:H2O in a ratio of about 1:5. In some embodiments, a concentration of an oxidant in the mixture may be in a range of about 0.1 to about 10⁷ ppm. The oxidant may include H2O2, O3, or the like.

The optional third etch operation follows the second etch operation, corresponding to act 2400 of FIG. 15, and may include the second etchant. Concentration of acid (e.g., HCl or organic acid) in the second etchant in the third etch operation may be in a range of about 0.1 wt % to about 50 wt %. In some embodiments, the concentration of acid is the same in the first etch operation and the third etch operation. In some embodiments, the concentration of acid is different in the third etch operation than in the first etch operation. For example, the concentration may be lower in the third etch operation than in the first etch operation or higher in the third etch operation than in the first etch operation. The third etch operation may be performed for a different length of time than that of the first etch operation. For example, the third etch operation may be performed for a length of time is shorter than that of the first etch operation.

FIG. 12Q is a cross-sectional view depicting a channel 22 having a gate dielectric layer 600 thereon. The channel 22 has a middle region 810 in which upper and lower surfaces of the channel 22 are substantially horizontal and flat. The channel 22 has left and right end regions 830L, 830R that are on either side of the middle region 810 and have curved side surfaces. In some embodiments, length of the channel 22 is in a range of about 8 nm to about 70 nm. The channel 22 has a first diagonal or “sheet diagonal” L1 that is in a range of about 10 nm to about 65 nm. The combination of the channel 22 and the gate dielectric layer 600 has a second diagonal L2. The second diagonal L2 exceeds the first diagonal L1, such as 0.2 nm<(L2−L1)<4 nm. The first diagonal L1 may be offset from a horizontal line L 3 of the channel 22 by a first angle θ1 that is in a range of about −45° to about 45°. The second diagonal L2 may be offset from the first diagonal by a second angle θ2 that is in a range of abou −45° to about 45°. In some embodiments, the first diagonal L1, the second diagonal L2, the first angle θ1 and the second angle θ2 are related by a relationship, such as 0.3 nm <(L2θ2−L1θ1)<6.3 nm.

The gate dielectric layer 600 includes corner regions or portions 600C. In the corner regions 600C, concentration of TiN in the gate dielectric layer 600 may exceed that outside of the corner regions 600C. Namely, deep intermixing between the layer 720 and the gate dielectric layer 600 may occur during plasma bombardment of the BARC 410, such that a relatively higher concentration of TiN is present in the corner regions 600C. The corner regions 600C generally are only on the upper side of the channel 22 and not on the lower side of the channel 22. This is because the upper side of the channel 22 and gate dielectric layer 600 are in a direct path of the plasma bombardment, whereas the lower side of the channel 22 and gate dielectric layer 600 are protected somewhat due to being in an indirect path of the plasma bombardment.

In some embodiments, although a mildly acidic etchant is used in the first and optionally third etching operations, some slight removal of material in the corner regions 600C due to the deep intermixing may still occur. As such, thickness of the gate dielectric layer 600 in the corner regions 600C may be slightly less than outside of the corner regions 600C. For example, a ratio of the thickness in the corner regions 600C to the thickness outside the corner regions 600C may be in a range of about 80% to about 99.5%, such as in a range of about 90% to about 99%. The thickness in the corner regions 600C may be conserved by using the mildly acidic etchant described with reference to FIG. 12P.

Because the BARC 410 over the first region 610 is removed via plasma bombardment whereas the BARC 410 over the second region 620 may be removed via ashing or another suitable method, the gate dielectric 600 in the second region 620 may not undergo deep intermixing with the layer 720. As such, the corner regions 600C in the first region 610 may be different in some respects than the corner regions 600C in the second region 620. For example, concentration of transition metal nitride in the corner regions 600C in the first region 610 may exceed concentration of transition metal nitride in the corner regions 600C in the second region 620. In another example, some slight removal of the deeply intermixed material in the corner regions 600C may take place during the removal of the layer 720 in the first region 610, such that thickness of the gate dielectric 600 in the corner regions 600C in the first region 610 may be less than that of the gate dielectric 600 in the corner regions 600C in the second region 620. For example, a ratio of the thickness in the corner regions 600C in the first region 610 to the thickness in the corner regions 600C in the second region 620 may be in a range of about 80% to about 99.5%, such as in a range of about 90% to about 99%.

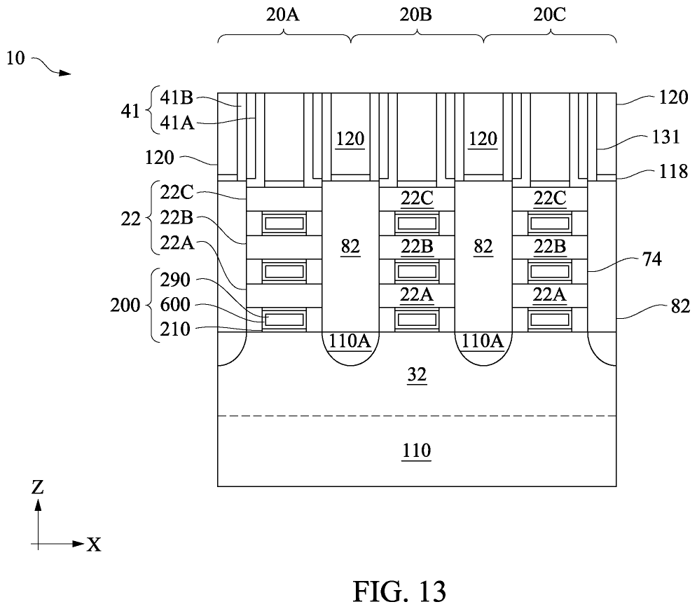

In FIG. 13, following formation of the gate structures 200, source/drain openings may be formed in the ILD 130 and source/drain contacts 120 may be formed in the source/drain openings. Silicide regions 118 and the source/drain contacts 120 are formed on the source/drain regions 82N, 82P.

In some embodiments, the silicide layers 118 are formed prior to formation of the source/drain contacts 120. For example, an N-type or P-type metal layer may be formed as a conformal thin layer over exposed portions of the source/drain regions 82N, 82P. The metal layer may be or include one or more of Ni, Co, Mn, W, Fe, Rh, Pd, Ru, Pt, Ir, Os or the like. In some embodiments, the metal layer is or includes one or more of Ti, Cr, Ta, Mo, Zr, Hf, Sc, Ys, Ho, Tb, Gd, Lu, Dy, Er, Yb or another suitable material. Following formation of the metal layer, the silicide layers 118 may be formed by annealing the device 10. Following the anneal, the silicide layers 118 may be or include one or more of NiSi, CoSi, MnSi, Wsi, FeSi, RhSi, PdSi, RuSi, PtSi, IrSi, OsSi, TiSi, CrSi, TaSi, MoSi, ZrSi, HfSi, ScSi, Ysi, HoSi, TbSI, GdSi, LuSi, DySi, ErSi, YbSi or the like. Silicide of the silicide layers 118 may diffuse into regions below the ESL 131. Thickness of the silicide layers 118 may be in a range of about 1 nm to about 10 nm. Below about 1 nm, contact resistance may be too high. Above about 10 nm, the silicide layers 118 may short with the channels 22B.

Following formation of the silicide layers 118, the source/drain contacts 120 are formed by filling the openings over the source/drain regions 82N, 82P with, for example, a liner layer and a fill layer. In some embodiments, the source/drain contacts 120 are formed by depositing a material that is or includes a conductive material such as Co, W, Ru, combinations thereof, or the like. In some embodiments, the source/drain contacts 120 are or include a Co-, W-or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. The source/drain contacts 120 land on the silicide layer 118 and are in contact with the ESL 131. Description of the device 10 and illustration thereof in many of the figures is given with reference to GAAFETs including vertical stacks of the nanostructures 22. In some embodiments, the silicide layers 118 and the source/drain contacts 120 are formed in and on source/drain regions 82N, 82P of FinFET devices.

Additional processing may be performed to finish fabrication of the nanostructure devices 20. For example, gate contacts (or gate vias) may be formed to electrically couple to the gate structures 200. An interconnect structure may then be formed over the source/drain contacts 120 and the gate contacts. The interconnect structure may include a plurality of dielectric layers (including, for example, a second ILD) surrounding metallic features, including conductive traces and conductive vias, which form electrical connection between devices on the substrate 110, such as the nanostructure devices 20, as well as to IC devices external to the IC device 10.

Embodiments may provide advantages. By etching the layer 720 using a mildly acidic etchant following plasma bombardment during BARC removal, etching of corner regions of the gate dielectric 600 that have deep intermixing with the transition metal nitride layer 720 is reduced or eliminated, which improves quality (e.g., thickness uniformity) of the gate dielectric 600. This can reduce lifetime degradation of threshold voltage (Vt), channel resistance (Rch), ring performance (RO %), time-dependent-dielectric-breakdown (TDDB) and maximum voltage of devices including the gate dielectric 600.

In accordance with at least one embodiment, a method includes: forming a stack of alternating first semiconductor channels and second semiconductor layers on a substrate; releasing the first semiconductor channels by removing the second semiconductor layers; forming a gate dielectric on the first semiconductor channels; forming a transition metal nitride layer on the gate dielectric; and exposing the gate dielectric in a first region of the substrate by removing the transition metal nitride layer. The removing includes: performing a first etch using an acidic etchant; and after the performing a first etch, performing a second etch using an oxidizing etchant.

In accordance with at least one embodiment, a method includes: releasing first semiconductor channels of a stack of alternating the first semiconductor channels and second semiconductor layers by removing the second semiconductor layers; forming a gate dielectric on the first semiconductor channels; forming a plurality of dummy plugs between adjacent pairs of the first semiconductor channels in a first region; forming a transition metal nitride layer on the gate dielectric in the first region and a second region; forming a bottom antireflective coating (BARC) layer on the transition metal nitride layer in the first and second regions; exposing the first region by patterning the BARC layer via plasma bombardment; and exposing the gate dielectric in the first region by removing the transition metal nitride layer. The removing includes: performing a first etch using a first acidic etchant; after the performing a first etch, performing a second etch using an oxidizing etchant; and after the performing a second etch, performing a third etch using a second acidic etchant.

In accordance with at least one embodiment, a device includes: a first stack of nanostructures in a first region; a second stack of nanostructures in a second region; and a first gate structure wrapping around the first stack of nanostructures. The first gate structure includes: a first gate dielectric having at least two first corner regions, the first corner regions being positioned at first upper corners of a first uppermost nanostructure of the first stack of nanostructures; and a first gate metal on the first gate dielectric. The device further includes a second gate structure wrapping around the second stack of nanostructures. The second gate structure includes: a second gate dielectric having at least two second corner regions, the second corner regions being positioned at second upper corners of a second uppermost nanostructure of the second stack of nanostructures; a transition metal nitride layer on the second gate dielectric; and a second gate metal on the transition metal nitride layer. Concentration of material of the transition metal nitride layer intermixed with the first gate dielectric exceeds that of the second gate dielectric.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first stack of nanostructures in a first region;
a second stack of nanostructures in a second region;
a first gate structure wrapping around the first stack of nanostructures, the first gate structure including:
a first gate dielectric having at least two first corner regions, the first corner regions being positioned at first upper corners of a first uppermost nanostructure of the first stack of nanostructures; and
a first gate metal on the first gate dielectric; and
a second gate structure wrapping around the second stack of nanostructures, the second gate structure including:
a second gate dielectric having at least two second corner regions, the second corner regions being positioned at second upper corners of a second uppermost nanostructure of the second stack of nanostructures;
a transition metal nitride layer on the second gate dielectric; and
a second gate metal on the transition metal nitride layer;
wherein concentration of material of the transition metal nitride layer intermixed with the first gate dielectric exceeds concentration of material of the transition metal nitride layer intermixed with the second gate dielectric.

2. The device of claim 1, wherein a first thickness of the first gate dielectric in the first corner regions is less than a second thickness of the second gate dielectric in the second corner regions.

3. The device of claim 2, wherein a ratio of the first thickness to the second thickness is in a range of about 80% to about 99.5%.

4. The device of claim 3, wherein the ratio is in a range of about 90% to about 99%.

5. The device of claim 1, wherein a first thickness of the first gate dielectric in the first corner regions is less than a third thickness of the first gate dielectric outside the first corner regions.

6. The device of claim 5, wherein a ratio of the first thickness to the third thickness is in a range of about 80% to about 99.5%.

7. A device, comprising:
a substrate;
a plurality of nanostructures over the substrate, the plurality of nanostructures comprising an uppermost nanostructure having a first diagonal and a gate dielectric layer on the uppermost nanostructure, the gate dielectric layer and the uppermost nanostructure together having a second diagonal that exceeds the first diagonal; and
a gate structure wrapping around the plurality of nanostructures, the gate structure comprising:
the gate dielectric layer having corner regions positioned at upper corners of the uppermost nanostructure; and
a gate metal on the gate dielectric layer,
wherein thickness of the gate dielectric layer in the corner regions is less than thickness of the gate dielectric layer outside the corner regions.

8. The device of claim 7, wherein a difference between the second diagonal and the first diagonal is in a range of about 0.2 nm to about 4 nm.

9. The device of claim 7, wherein the first diagonal is in a range of about 10 nm to about 65 nm.

10. The device of claim 7, wherein a length of the uppermost nanostructure is in a range of about 8 nm to about 70 nm.

11. The device of claim 7, wherein the gate dielectric layer comprises a high-k dielectric material having a dielectric constant greater than a dielectric constant of silicon oxide.

12. The device of claim 11, wherein the high-k dielectric material comprises at least one of HfO2, ZrO2, or a combination thereof.

13. The device of claim 7, wherein concentration of material of a transition metal nitride layer intermixed with the gate dielectric layer in the corner regions exceeds concentration of material of the transition metal nitride layer intermixed with the gate dielectric layer outside the corner regions.

14. The device of claim 7, wherein a ratio of the thickness of the gate dielectric layer in the corner regions to the thickness of the gate dielectric layer outside the corner regions is in a range of about 80% to about 99.5%.

15. A device, comprising:
a first nanostructure transistor in a first region, the first nanostructure transistor comprising:
a first stack of nanostructures;
a first gate dielectric layer wrapping around the first stack of nanostructures, the first gate dielectric layer having first corner regions at upper corners of a first uppermost nanostructure of the first stack of nanostructures, the first gate dielectric layer having a first thickness in the first corner regions and a second thickness outside the first corner regions, the first thickness being less than the second thickness; and
a first gate metal on the first gate dielectric layer; and
a second nanostructure transistor in a second region, the second nanostructure transistor comprising:
a second stack of nanostructures;
a second gate dielectric layer wrapping around the second stack of nanostructures;
a transition metal nitride layer on the second gate dielectric layer; and
a second gate metal on the transition metal nitride layer,
wherein the first gate dielectric layer is free of a discrete transition metal nitride layer between the first gate dielectric layer and the first gate metal.

16. The device of claim 15, wherein the first nanostructure transistor comprises an N-type field-effect transistor and the second nanostructure transistor comprises a P-type field-effect transistor.

17. The device of claim 15, wherein the transition metal nitride layer comprises TiN.

18. The device of claim 15, wherein a ratio of the first thickness to the second thickness is in a range of about 90% to about 99%.

19. The device of claim 15, wherein the second gate dielectric layer has second corner regions at upper corners of a second uppermost nanostructure of the second stack of nanostructures, and wherein concentration of material of the transition metal nitride layer intermixed with the first gate dielectric layer in the first corner regions exceeds concentration of material of the transition metal nitride layer intermixed with the second gate dielectric layer in the second corner regions.

20. The device of claim 15, wherein the first gate dielectric layer and the second gate dielectric layer each comprise at least one of HfO2, HfSiO, HfZrO, ZrO2, Ta2O5, or a combination thereof.
